(19) United States
(12) Patent Application Publication
(10) Pub. No.: US 2024/0407110 A1
(43) Pub. Date: Dec. 5, 2024

(54) DOOR OR WALL PANEL MOUNT AND USB CONNECTION FOR HUMAN INTERFACE MODULE (HIM)

(71) Applicant: Rockwell Automation Technologies, Inc., Mayfield Heights, OH (US)

(72) Inventors: Bruce Weiss, Milwaukee, WI (US); Marius Chis, Cambridge (CA); Joseph Riley, Grafton, WI (US); Julia Keegan, Madison, WI (US); Elsa Copes, Cedarburg, WI (US)

(73) Assignee: Rockwell Automation Technologies, Inc., Mayfield Heights, OH (US)

(21) Appl. No.: 18/204,940

(22) Filed: Jun. 1, 2023

(51) Int. Cl. H05K 5/02; H05K 5/00

(52) U.S. Cl. CPC H05K 5/0217; H05K 5/0017

(57) ABSTRACT

A human interface module includes a body. At least one input device and at least one output device are connected to the body. A mounting protrusion projects outwardly from the body and that is adapted to be received through a mounting aperture defined in a door or other cabinet panel for fixedly securing said body to the panel. The mounting aperture can be punched and include an alignment notch that receives a locator nib of the mounting protrusion. A nut can be advanced on a threaded portion of the mounting protrusion to secure the body to the panel. The body can be a bezel that receives a removable interface module. A USB Type-C or other electrical connector can be connected to the body and is adapted to mate with a corresponding mating connector of a cable. The connector can be accessible through a hollow core of the mounting protrusion.

### BACKGROUND INFORMATION

A motor control system, often referred to as a “motor drive,” can include a human interface module (HIM) including a keypad, touch screen, and other input devices and a visual display screen, indicator lights, and other output devices by which an operator can input parameters and other data to and receive output data from the motor drive to which the HIM is operably connected. Such HIM devices are also used on similar electrical equipment other than motor drives. The HIM can be mounted directly to the motor drive or can be mounted to a wall panel such as a movable door panel or a fixed wall panel of a cabinet in which the motor drive is located so that operators can provide input to and receive output from the motor drive without opening the door panel or other access panel of the cabinet. In such cases, the HIM mounted to the door panel or other wall panel is electrically operably connected to the motor drive contained within the cabinet by a cable that carries power to the HIM and that carries data signals to and from the HIM and the motor drive. The cable can be configured as cable that supports power delivery and serves as a communications transport, such as USB, Drive Peripheral Interface, and others.

Known systems for connecting the HIM to the door (movable wall) panel or a fixed wall panel of the cabinet have been found to be suboptimal, as have the known DPI cable interface systems for connecting the door-mounted HIM to the motor drive. In particular, known systems for mounting a HIM to a door or other wall panel of the cabinet require that an installer drill multiple holes in the door/panel (e.g., 4-7 holes) in a predefined pattern that must exactly match the pattern of fasteners used to mount the HIM to the door panel. Some of the holes have a first diameter to receive the HIM mounting fasteners while at least one other hole must be formed of a different size for passage of the drive interface cable. The installer must use a plurality of fasteners to mount the HIM to the door or other panel. The installer must also install a cable grommet in the aperture through which the cable passes to protect the cable.

### BRIEF DESCRIPTION

In accordance with one aspect of the present development, a human interface module includes a body. At least one input device and at least one output device are connected to the body. A mounting protrusion projects outwardly from the body and that is adapted to be received through a mounting aperture defined in an associated cabinet panel for fixedly securing said body to the associated cabinet panel.

In accordance with another aspect of the present development, a method of mounting a human interface module to a cabinet panel includes forming a mounting aperture in a panel and locating a body of a human interface module adjacent the panel with a mounting protrusion of the body extending through the mounting aperture. A mounting nut is advanced on an externally threaded portion of the mounting protrusion to capture the panel between the mounting nut and the body of the human interface module, or an annular or C-shaped lock ring, lock clip or other lock member is secured to the mounting protrusion to capture the panel between the lock member and the body of the human interface module.

In accordance with a further aspect of the present development, an interface module for a motor drive includes a body. At least one input device and at least one output device are connected to the body. An electrical connector, such as a USB Type-C or other power/data connector is connected to the body and adapted to mate with a corresponding mating connector of a motor drive cable.

### BRIEF DESCRIPTION OF THE DRAWINGS

FIG. 1 (prior art) shows a motor drive system including a door-mounted HIM device.

FIG. 1A (prior art) is an enlarged view of the door-mounted HIM device of FIG. 1.

FIG. 2 (prior art) is an exploded perspective view of the HIM device of FIG. 1 as mounted to a cabinet door panel.

FIG. 3 (prior art) shows another known door-mounted HIM device including a door-mounted bezel and a HIM that is selectively installed on or removed from the bezel.

FIGS. 4A & 4B respectively show rear isometric and side views of a door-mounted HIM device provided in accordance with an embodiment of the present development.

FIG. 4C is a section view of the door-mounted HIM device of FIGS. 4A & 4B.

FIG. 5 is a partial view of a cabinet door panel including a single HIM mounting aperture defined therein and adapted for mounting a HIM device to the door panel in accordance with an embodiment of the present development.

FIG. 6 is a side view of the HIM device of FIGS. 4A & 4B operatively connected to a door or other panel.

FIG. 7A is a front view that shows an alternative HIM device provided in accordance with an embodiment of the present development including a door-mounted bezel and a removable interface module selectively installed in or removed from the door-mounted bezel.

FIG. 7B is a side view that shows the HIM device of FIG. 7A operatively connected to a door or other cabinet panel.

FIG. 8 is a rear isometric view of the HIM device of FIGS. 4A & 4B or the bezel mounted HIM device H2 of FIGS. 7A & 7B including a power/data cable (such as a USB-C cable) operatively connected thereto and including a cable-retainment clip operatively connected thereto.

FIG. 9 shows another alternative HIM device without the mounting protrusion and/or with the mounting protrusion removed;

FIG. 10 is a partial enlarged view that shows the HIM device of FIG. 4A or FIG. 7A including an alternative torque limiting mounting nut in place of the conventional nut of FIGS. 6 & 7B.

FIG. 10A is an isometric view that shows the torque limiting mounting nut by itself.

### DETAILED DESCRIPTION

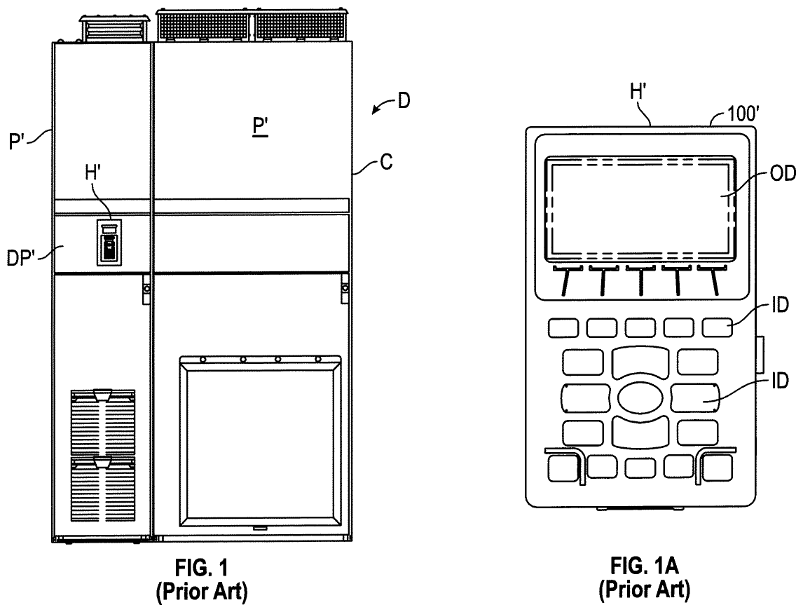

FIG. 1 illustrates a motor control system or “motor drive” D that is generally known in the art. The motor drive D is housed within a cabinet C that can be defined from sheet metal and that includes a plurality of panels P′ that are assembled to define an enclosure for the motor drive components. One or more of the panels P′ can be movable or removable such as a door panel DP′ that can pivot relative to the other panels of the cabinet C to provide access to the motor drive components inside the cabinet C.

The motor drive D includes a Human Interface Module (HIM) H′ mounted on a panel P′ such as the door panel DP′. With reference also to FIG. 1A, the HIM H′ includes a body 100′ containing one or more input devices (ID) such as a keypad, touch screen, voice input device, and/or other input device(s) and includes one or more output devices OD such as a visual display, indicator lights, speaker, and/or other output device(s) by which a human operator can input data such as operating parameters to the motor drive and by which the human operator can receive output data such as operating parameters and status data from the motor drive D.

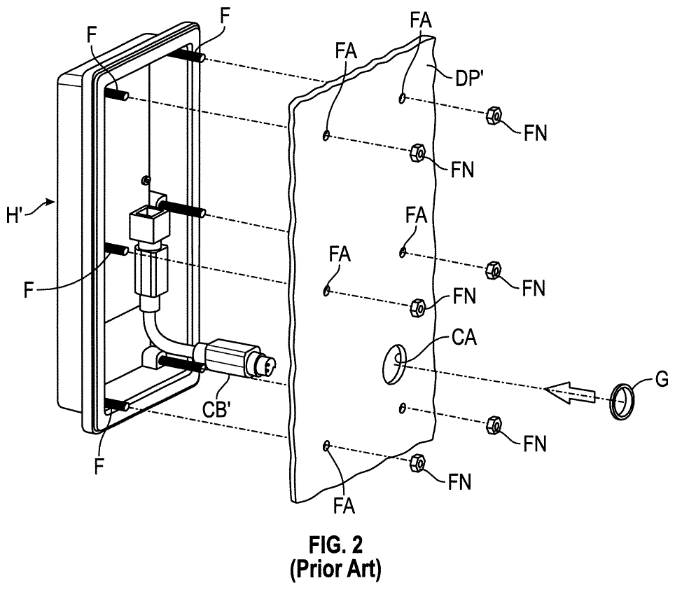

FIG. 2 (prior art) provides a rear exploded isometric view of the HIM H′ and door panel DP′ of FIG. 1, particularly the method and structure for operably mounting the HIM H′ to the door panel DP′. Multiple fastener mounting apertures FA are drilled through the door panel DP′ in a pre-defined geometric pattern that corresponds exactly with the pattern of fasteners F used to fixedly secure the HIM H′ to the door panel DP′ so that the fasteners F can be respectively received into the fastener mounting apertures FA and be captured by a plurality of fastener nuts FN respectively threadably engaged with the fasteners F. In addition, a cable aperture CA must also be drilled or punched through the panel DP′ to allow for the passage of a HIM power and data cable CB′ that is operatively connected to the motor drive D for transmission of data between the HIM device H′ and the motor drive D and also for transmission of electrical power to the HIM device H′. A grommet G must also be secured in the cable aperture CA to protect the cable CB′. As such, those of ordinary skill in the art will recognize that the known installation process for the known HIM H′ is suboptimal in that it requires the installer to form the multiple apertures FA,CA, with the fastener apertures FA located in the exact required pattern, and then install the grommet G and the multiple fastener nuts FN.

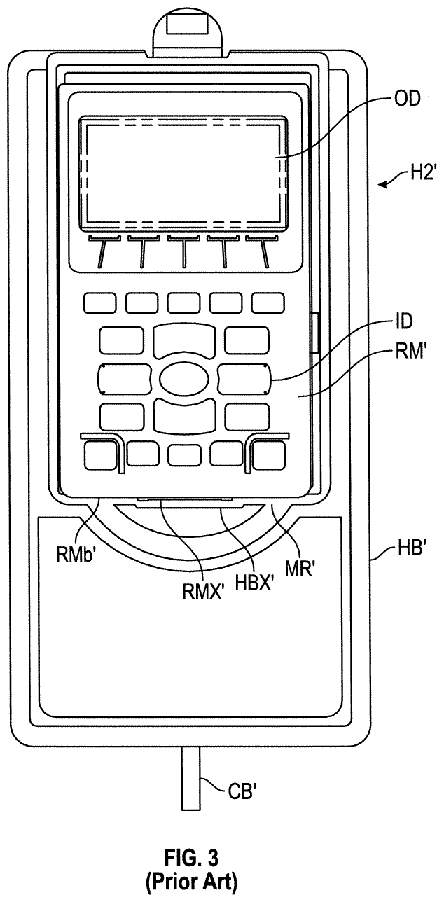

FIG. 3 (prior art) shows another known door-mounted HIM device H2′ in which the body 100′ comprises a panel-mounted (such as door-mounted) bezel HB′ and a removable interface module RM′ is selectively installed on or removed from a recess or other module receiving location MR′ of the bezel HB′. The removable module RM′ includes the input and output devices ID,OD as described above in relation to the HIM H′. The removable module RM′ also includes an electronic connector RMX′ that can be located on a bottom body edge RMb′ and that mates with a corresponding electrical connector HBX′ located in the mounting recess MR′ of the bezel HB′ when the removable module RM′ is connected to the bezel HB′. The bezel connector HBX′ is connected to the power and data cable CB′ which is also operably connected to the motor drive D at an opposite end for transmission of data between the removable module RM′ and the motor drive D and also for transmission of electrical power to the removable module RM′ when the removable module RM′ is connected to the bezel HB′ and the connectors RMX′,HBX′ are mated. In such an embodiment, a human operator can selectively remove the removable HIM module RM′ from mounting recess MR′ of the bezel HB′ and enter input data/parameters into or receive output data/parameters from the removable module RM′ while the removable module RM′ remains connected to the motor drive D by a cable or at a location remote from the motor drive cabinet C (and bezel HB′) provided that the removable module RM′ is connected to a power source at such remote location (data transfer between the removable HIM module RM′ and motor drive D only occurs when the removable module RM′ is operably seated in the mounting bezel HB′ or otherwise connected to the motor drive by a cable). The removable module RM′ can communicate with the motor drive D via cable CB′ when the removable module RM′ is once-again connected to the bezel HB′ such that the connectors RMX′,HBX′ are mated. Mounting the bezel HB′ to the door panel DP or other panel P is similar to the mounting procedure for the HIM device H′ with the same deficiencies as described above in relation to FIG. 2.

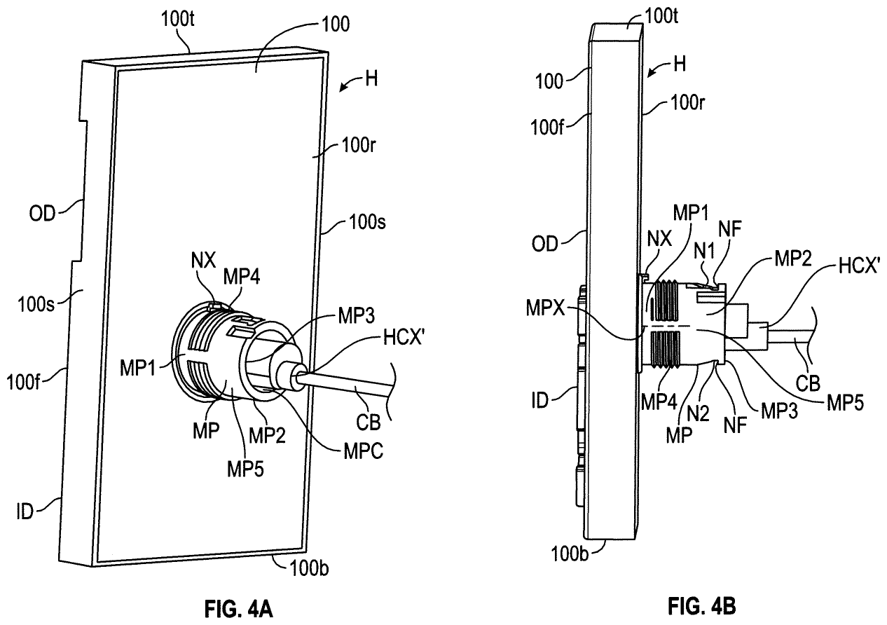

FIGS. 4A & 4B (collectively FIG. 4) respectively show rear isometric and side views of a door-mounted HIM device H provided in accordance with an embodiment of the present development. FIG. 4C is a partial section view of the HIM device H. Except as otherwise shown and/or described herein, the HIM device H is the same as the HIM device H′ and like components are not necessarily described here again. The HIM device can be used in place of the HIM device H′ on the motor drive D. The HIM device H comprises a body 100 including a front surface or side 100f, an opposite rear surface side 100r, a top surface or side 100t, an opposite bottom surface or side 100b, and opposite first (left) and second (right) lateral surfaces or sides 100s. The body 100 contains and includes the electronic circuits and components required to perform the data input and output functions described above in relation to the HIM device H′ including input device(s) ID and output device(s) OD as described above.

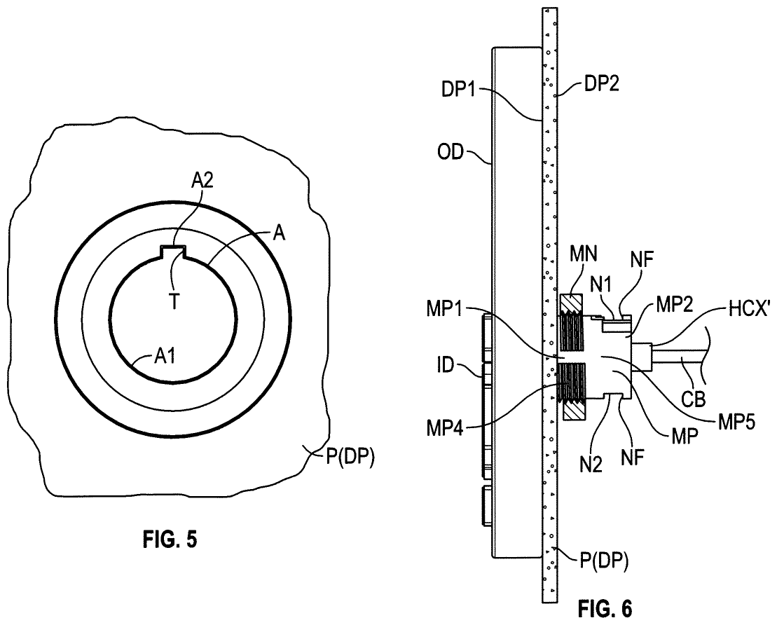

Unlike the HIM device H′, the HIM device H comprises a mounting extension or mounting protrusion MP that projects outwardly from the rear side 100r of the body 100 along and about a longitudinal axis MPX. The mounting protrusion MP can comprise a generally cylindrical or outer shape defined about the longitudinal axis and can be centrally located between the first and second lateral sides 100s of the body and/or can also be centrally located between the top and bottom sides 100t, 100b of the body but need not be. The mounting protrusion MP includes an inner end MP1 connected to and/or formed as part of the body rear side 100r and includes an outer end MP2 that is spaced axially outward from the inner end MP1 and from the rear surface 100r. The outer end MP2 includes an open end MP3 that opens into a hollow core MPC. Between the inner and outer ends MP1,MP2, the mounting portion MP includes a cylindrical portion MP4 that can comprise an external helical thread so as to be externally threaded and adapted to operably receive a mounting nut MN (FIG. 6) thereon to secure the HIM body 100 to a door panel DP or other panel P as described in more detail below.

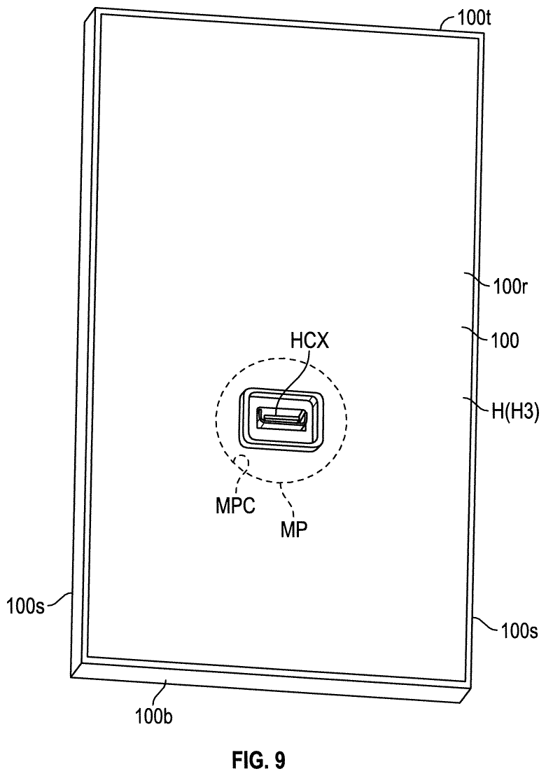

The rear side 100r of the HIM body 100 includes a HIM electrical connector HCX connected thereto (see also FIG. 9 in which the mounting projection MP is omitted or has been removed and is diagrammatically shown with a broken line), and the mounting protrusion MP can encircle or circumferentially surround the electrical connector HCX and include a hollow central region or core MPC that opens through the outer end MP3 to allow access to the electrical connector HCX for the mating connector HCX′ of the drive cable CB (and any desired adapter AP or the like that may also be included). The HIM connector HCX is electrically connected to the electronic components and devices of the HIM H including the input and output devices ID,OD through one or more printed circuit board assemblies PCBA (FIG. 4C). The HIM connector HCX can be a receptable connector that opens through the rear side 100r of the HIM body 100 for mating with a corresponding plug connector HCX′ of a HIM cable CB as described in more detail below for transmission of data between the HIM H and the motor drive D and for transmission of electrical power to the HIM H. Alternatively, the electrical connector HCX can be a plug connector that projects outwardly from the rear housing side 100r.

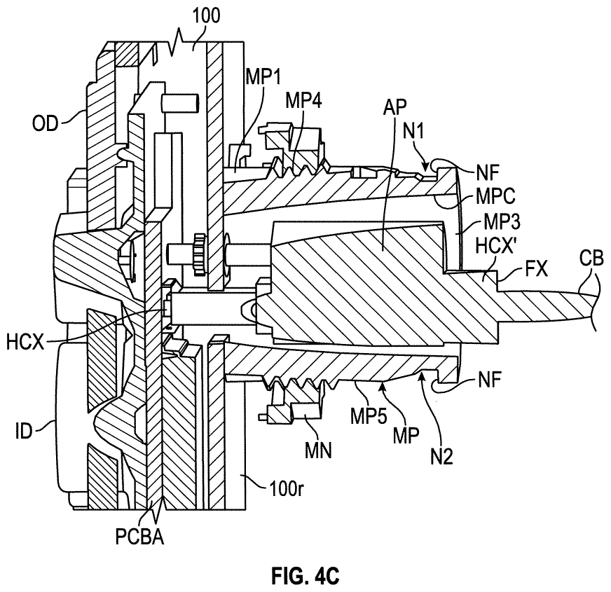

The HIM H can further comprise a locator nib NX located adjacent the inner end MP1 of the mounting projection MP. The locator nib NX can be located at the inner end MP1 of the mounting protrusion MP and can be connected to the body rear side 100r and/or an outer surface of the mounting protrusion MP axially inward from the externally threaded portion MP4. The locator nib NX is located or extends radially outward relative to the externally threaded surface MP4 and can also extend axially outward away from the body rear side 100r. As described below, the locator nib NX mates with and is received in a corresponding notch T (FIG. 5) formed in the door panel DP or other panel P of the cabinet C as part of a HIM mounting aperture A in order to locate the HIM body 100 in a select angular position or orientation relative to the door panel DP or other panel P. The locator nib NX can be located circumferentially such that the HIM body 100 is located in its required or preferred operational orientation when the locator nib NX is oriented in the 12 O'clock position (the uppermost or top vertical position). The locator nib NX can be removed by a razor blade, screwdriver blade, or the like if desired. In one example, multiple nibs NX are provided and all but one are removed depending upon the desired or required installation orientation of the HIM body 100.

The entire mounting protrusion MP can be defined as a one-piece construction as part of the HIM body 100 but can alternatively be selective connected to and/or removed from the rear side 100r of the body 100 of the HIM H (see FIG. 9 where the mounting protrusion is removed or omitted and shown only with a broken line). In one such example, the mounting protrusion MP is defined as a one-piece molded polymeric structure as part of the body 100 of the HIM H, and can be cut, severed, or otherwise removed from the HIM body 100 if not needed for a particular application. For example, the intersection of the inner end MP1 of the mounting protrusion MP with the rear side 100r of the body 100 can be defined as a weakened or frangible zone that can be broken or severed with application of a force transverse to the longitudinal axis MPX of the mounting protrusion MP. In another embodiment, the mounting protrusion MP can be friction fit, adhesively connected, threadably connected, and/or otherwise selectively connected to the rear side 100r of the HIM body 100 when needed and disconnected if not needed for a particular application such as when the HIM H is mounted on the drive D itself rather than a panel P,DP of a cabinet.

Between the externally threaded portion MP4 and the outer end MP2, on its outer surface MP5, the mounting protrusion MP comprises at least one and preferably at least two undercut notches such as the first and second undercut notches N1,N2 as shown in the illustrated example. The undercut notch(es) can be located at the outer end MP2 of the mounting protrusion MP. The first and second undercut notches can be located at circumferentially spaced-apart locations relative to each other such as at diametrically opposed positions so as to be generally arranged opposite each other with respect to a longitudinal axis MPX of the mounting protrusion MP. Each undercut notch comprises an inner surface that extends parallel to the longitudinal axis MPX and a transverse lock face Nf that extends outwardly so as to be transversely oriented relative to the longitudinal axis MPX and that is oriented so as to face inwardly toward the body rear side 100r and toward the inner end MP1 of the mounting protrusion MP. In the illustrated example, the transverse lock face Nf extends radially outward and is perpendicularly oriented relative to the longitudinal axis MPX and the inner surface Na and can be arranged parallel to the rear side 100r of the body 100.

In accordance with one embodiment of the present development and in contrast with known methods/structures, the HIM device H can be connected to the door panel DP or other panel P using only a single HIM mounting aperture A formed in the panel DP,P. By way of example, FIG. 5 shows a door panel DP (or any panel P) including a HIM mounting aperture A formed therein to define a door panel DP (or other panel P) in accordance with an embodiment of the present invention. The HIM mounting hole or mounting aperture A can be drilled or otherwise formed, but is preferably formed using a punch such as a push-button mounting hole punch or the like and can have a standard push-button mounting hole diameter such as 22 mm, 22.5 mm, 30 mm, 35 mm or a different non-standard diameter. In the illustrated example, the HIM mounting aperture A is defined using a notched punch such that the HIM mounting aperture A comprises a first portion A1 defined by a circular arc of approximately 350 degrees, and a second portion A2 comprising a radially enlarged angular alignment notch T that interrupts and forms a circumferential gap in the first portion A1 of approximately 10 degrees. The angular alignment notch T opens into the mounting aperture A. In one example as shown, the notch T is located at the 12 o'clock position but this can vary. Also, more than one angular alignment notch T can be provided. The angular alignment notch T is dimensioned and located to closely receive the locator nib NX of the mounting protrusion of the HIM body 100 when the HIM body 100 is oriented in a select angular position relative to the panel DP,P so that locator nib NX is aligned with and received in the angular alignment notch T whereby the mounting protrusion MP (and entire HIM body 100) is restrained against rotation about the longitudinal axis MPX, except for minimal rotation of less than 5 degrees or less due to tolerance gaps and clearance gaps required for the locator nib NX to be received in the notch N. In two non-limiting examples, the alignment notch(es) T can have a width of 3.2 mm for a 22 mm diameter mounting aperture A or the alignment notch(es) T can have a width of 4.57 mm for a 30 mm diameter mounting aperture A, but it is not intended that the present development be limited to any particular size mounting aperture A or alignment notch T. If the mounting protrusion of the HIM body 100 includes multiple locator nibs NX, the HIM mounting aperture A can be defined to include at least the same number of notches T such that each locator nib NX is received in a respective notch T or all but one of the locator nibs NX can be removed as described above. If multiple notches T are provided (e.g., at a 12 o'clock position and at the 9 o'clock and/or 3 o'clock position), the locator nib NX of the HIM body 100 can be located in any one of the multiple notches T to install the HIM body 100 in the desired angular orientation. Those of ordinary skill in the art will recognize that when the locator nib NX is received in a notch T, the angular position of the HIM body 100 about the longitudinal axis MPX of the mounting protrusion MP is fixed in that the engagement of the locator nib NX in a notch T prevents angular movement of the HIM body 100 relative to the panel DP,P in which the HIM mounting aperture A is formed.

FIG. 6 shows the HIM H operatively connected to the door panel DP of FIG. 5, with its mounting protrusion MP located in and extending through the mounting aperture A. The rear side 100r of the HIM body 100 is abutted with or located close to an outer side DP1 of the door panel DP (a gasket, not shown, can be located between the HIM body rear side 100r and the door panel outer side DP1) and with the locator nib NX located in the notch T of the mounting aperture A. A mounting nut MN is operably engaged with the externally threaded portion MP4 of the mounting protrusion MP and advanced toward the rear side DP2 of the door panel DP to capture the door panel DP between the mounting nut MN (and any seal S and/or washer that may also be included) on the one side and the rear side 100r of the HIM body 100 (and any seal and/or gasket that may be included) on the other side.

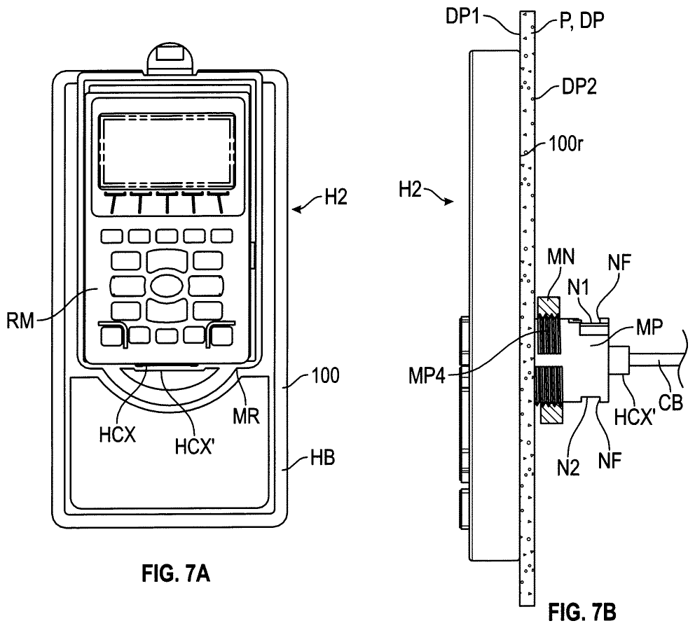

FIG. 7A is a front view that shows an alternative HIM device H2 provided in accordance with an embodiment of the present development, wherein the HIM body 100 comprises and is provided as a door-mounted bezel HB, and a removable module RM selectively installed in or removed from a module receiving recess MR of the door-mounted bezel HB. The HIM device H2 is the same as the bezel mounted HIM device H2′ described above except as otherwise shown and/or described herein. In particular, unlike the known bezel mounted HIM device H2′, the bezel mounting HIM device H2 comprises, as shown in FIG. 7B, the same mounting protrusion MP as described above in relation to the HIM device H. The mounting protrusion MP projects outwardly from the rear side 100r of the body 100. FIG. 7B is a side view that shows the bezel mounted HIM device H2 of FIG. 7A operatively connected to the door panel DP (or other panel P) including the notched aperture A of FIG. 5 in the same manner as the HIM device H.

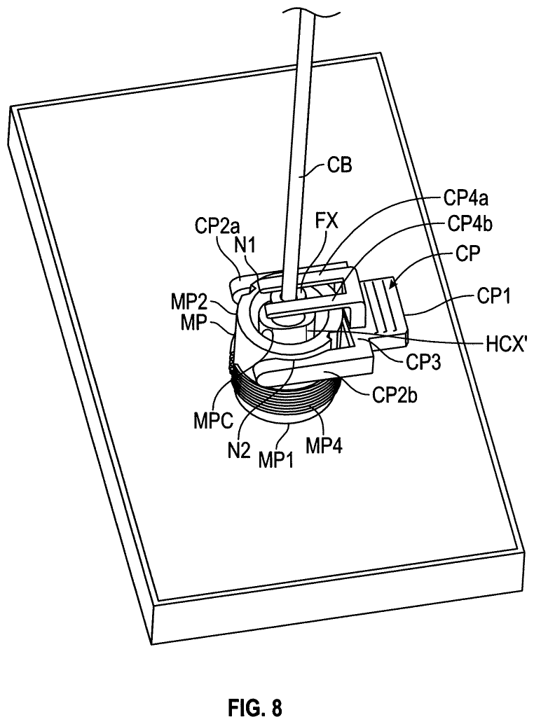

As noted above, the HIM device H, H2 includes a HIM electrical connector HCX connected thereto (see also FIG. 9). As shown, the electrical connector HCX is a receptacle connector that mates with a corresponding plug connector HCX′ located on a first or outer end CB of a cable that carries electrical power to the HIM device H,H2 and that carries data bi-directionally between the HIM device H,H2 and the motor drive D. Alternatively, the electrical connector HCX is a plug connector that mates with a corresponding receptacle connector HCX′ located on the first or outer end CB of the cable that carries electrical power to the HIM device H,H2 and that carries data bi-directionally between the HIM device H,H2 and the motor drive D. With reference now also to FIG. 8, to prevent the cable plug connector HCX′ from axially separating from the corresponding receptable connector HCX with which it is mated, a HIM device H,H2 provided in accordance with the present development can optionally further comprise a cable retainment clip CP that is selectively connected to the mounting protrusion MP and that engages the plug connector HCX′ and prevents axial movement of the plug connector HCX′ away from the receptacle connector HCX that would result in separation of the connectors HCX,HCX′. In particular, the cable retainment clip CP can comprise a one-piece body CP1 that can be metal or a molded polymeric structure. The body CP1 can comprise first and second legs CP2a, CP2b connected by a base CP3. The first and second legs CP2a, CP2b can be parallel and spaced-apart with respect to each other and that are adapted to be respectively received in the first and second undercut notches N1, N2 of the mounting protrusion so as to be located adjacent the respective lock faces Nf thereof. The cable retainment clip CP further comprises a least one and preferably first and second plug engagement tines CP4a, CP4b that are connected to and extend outwardly from the base CP3 generally between the first and second legs (but not necessarily in the same plane as the legs CP2a, CP2b). In the illustrated example, the first and second plug engagement tines CP4a, CP4b are arranged parallel to each other and also parallel to the first and second legs CP2a, CP2b. When the cable retainment clip CP is operatively connected to the mounting protrusion MP with the first and second legs CP2a,CP2b respectively located in the undercut notches N1,N2, the first and second plug engagement tines CP4a, CP4b receive the cable CB in a space defined between the tines CP4a, CP4b and the tines CP4a, CP4b are each engaged with an outer transverse face FX of the plug HCX′. When the cable retainment clip CP is operatively installed, the lock faces Nf of the respective notches N1,N2 inhibit or block outward axial movement of the clip CP away from the rear side 100r of the HIM body 100 and the one or more tines CP4a, CP4b inhibit or block outward axial movement of the cable plug HCX′ away from the mated receptacle connector HCX that would result in disconnection of the plug connector HCX′ from the receptacle connector HCX.

In one example, the receptacle and plug connectors HCX, HCX′ can be provided in accordance with a USB standard such as the USB Type-C (also referred to as “USB-C”) standard. With reference to FIG. 7A, in accordance with an embodiment of the present development, the removable module RM can include the USB-C receptacle connector HCX on its bottom edge in place of the known removable module connector RMX′ described above in relation to FIG. 3 and the bezel HB can include the USB-C plug connector HCX′ in place of the known bezel connector HBX′. As such, the removable module RM includes an electronic receptable connector HCX that mates with a corresponding electrical plug connector HCX′ located in the module receiving location MR of the bezel HB when the removable module RM is operatively installed in the module receiving location MR of the bezel HB to define the HIM device H2.

FIG. 9 shows the HIM device H with the mounting protrusion MP omitted or removed to provide a HIM device H3 that can be mounted directly to a motor drive D or another location where the mounting protrusion MP is not required or desired. In such case, the HIM connector HCX remains located on and opens through the rear side 100r of the HIM body 100. In such an embodiment, the HIM device H3 can pivot and snap into a HIM mounting location or receptacle located on the motor drive D and/or a door-mounted bezel such as the bezel HB in which the mating plug connector HCX′ is located to be inserted into the HIM electrical connector HCX when the HIM device H3 is installed with a pivoting, translating or sliding motion.

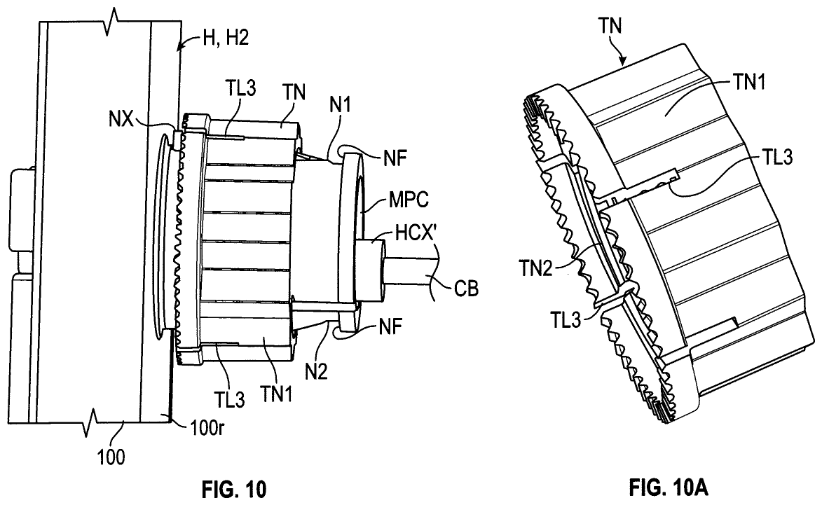

FIG. 10 is a partial enlarged view that shows the HIM device of FIG. 4A or FIG. 7A including an alternative torque-limiting mounting nut TN in place of the conventional mounting nut MN of FIGS. 6 & 7B. The torque-limiting mounting nut TN is shown by itself in FIG. 10A. The nut TN comprises a one-piece molded polymeric body TN1 comprising an internally threaded aperture TN2 that is dimensioned and conformed to threadably mate with the externally threaded portion MP4 of the mounting protrusion MP. Unlike the conventional mounting nut MN, the torque-limiting mounting nut TL comprises at least one and preferably two or more (a plurality of) axially extending torque-relief slits TL3. The nut TL is advanced on the externally threaded portion MP4 of the mounting protrusion MP in a conventional manner. However, unlike a conventional nut MN, when the torque-limiting nut is advanced to it preferred installation torque, additional torque applied to advance the nut causes the nut body TL1 to radially expand due to the presence of the torque-relief slits TL3 such that the nut TL is not further advanced on the externally threaded portion MP4. In this manner, use of the torque-limiting nut TL limits physical stress on the mounting protrusion MP and other parts of the HIM body 100 or bezel HB. The torque-limiting nut TL can be removed in a conventional manner by reverse rotation on the externally threaded portion MP4.

In the preceding specification, various embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

The following is claimed:

1. A human interface module comprising:
a body;
at least one input device and at least one output device connected to the body;
a mounting protrusion that projects outwardly from said body and that is adapted to be received through a mounting aperture defined in an associated cabinet panel for fixedly securing said body to the associated cabinet panel.

2. The human interface module as set forth in claim 1, further comprising an electrical connector operably connected to said at least one input device and said at least one output device, wherein said electrical connector is connected to said body and located within a hollow core of said mounting protrusion and said mounting protrusion includes an open outer end that provides access to the electrical connector.

3. The human interface module as set forth in claim 2, wherein said mounting protrusion comprises an inner end connected to a rear side of said body and an opposite outer end spaced outwardly along a longitudinal axis from said inner end and away from said rear side of said body, and the mounting protrusion further comprises one or more cable retention features to facilitate retention of an associated cable that connects with the electrical connector.

4. The human interface module as set forth in claim 3, wherein said mounting protrusion is selectively removable from said body.

5. The human interface module as set forth in claim 2, wherein said electrical connector comprises a USB connector.

6. The human interface module as set forth in claim 3, wherein said one or more cable retention features comprise at least one undercut notch located on said mounting protrusion and including a lock face oriented transversely relative to said longitudinal axis and facing toward said inner end of said mounting projection.

7. The human interface module as set forth in claim 6, wherein said at least one undercut notch comprises first and second undercut notches that are arranged opposite each other.

8. The human interface module as set forth in claim 7, further comprising a cable retainment clip adapted to be connected to said mounting protrusion to retain an associated plug connector and cable in engagement with said electrical connector, said cable retainment clip comprising first and second legs adapted to be received respectively in said first and second undercut notches.

9. The human interface module as set forth in claim 8, wherein said cable retainment clip further comprises first and second tines that are adapted to receive the associated cable therebetween and engage a transverse face of the associated plug connector.

10. The human interface module as set forth in claim 8, wherein said electrical connector comprises a USB Type-C receptacle connector and wherein the associated plug connector is a USB Type-C plug connector.

11. The human interface module as set forth in claim 1, wherein said mounting protrusion comprises an inner end connected to a rear side of said housing and comprises an outer end spaced axially outward from said inner end, and wherein said mounting projection further comprises an externally threaded portion between its inner and outer ends, said human interface module further comprising a mounting nut threadably engaged with said externally threaded portion of said mounting protrusion and adapted to capture the associated cabinet panel between the mounting nut and the rear side of the housing.

12. The human interface module as set forth in claim 11, wherein the mounting nut is a torque-limiting nut comprising a nut body and at least one axially extending slit defined in the nut body that allows the body to expand radially when a select torque is applied to the nut body.

13. The human interface module as set forth in claim 11, further comprising a locator nib projecting outwardly from the mounting protrusion and adapted to be received in a locating notch portion of the mounting aperture of the associated cabinet panel.

14. The human interface module as set forth in claim 1, wherein:
said body comprises a bezel including a receiving location that receives a removable HIM module.

15. A method of mounting a human interface module to a cabinet panel, said method comprising:
forming a mounting aperture in the panel;
locating a body of a human interface module adjacent the panel with a mounting protrusion of the body extending through the mounting aperture;
advancing a mounting nut on an externally threaded portion of said mounting protrusion to capture the panel between the mounting nut and the body of the human interface module.

16. The method of mounting a human interface module as set forth in claim 15, wherein the mounting nut is a torque-limiting nut comprising a nut body and at least one axially extending slit defined in the nut body that allows the body to expand radially when a select torque is applied to the nut body.

17. The method of mounting a human interface module as set forth in claim 15, wherein said step of forming said mounting aperture in the panel comprises forming the mounting aperture to include at least one angular alignment notch and wherein said step of locating said body of said human interface module adjacent the panel with said mounting protrusion of the body extending through the mounting aperture includes angularly aligning said body such that a locator nib projecting outwardly from the mounting protrusion is aligned with and received in said angular alignment notch.

18. The method of mounting a human interface module as set forth in claim 15, wherein
said body comprises a bezel including a receiving location that receives a removable HIM module.

19. The method of mounting a human interface module as set forth in claim 15, wherein said step of forming a mounting aperture in the panel comprising forming a standard push-button mounting aperture, wherein said standard push-button aperture has a diameter selected from the group comprising: 22 mm; 22.5 mm, 30 mm, 35 mm.

20. A human interface module for a motor drive comprising:
a body;
at least one input device and at least one output device connected to the body;
a USB Type-C electrical connector connected to said body and adapted to mate with a corresponding mating USB Type-C connector of a motor drive cable.

21. The human interface module as set forth in claim 20, wherein said USB Type-C electrical connector is one of:
located on a rear side of the body and encircled by a hollow-core mounting protrusion that projects outwardly from the rear side of said body, said mounting protrusion adapted to be received through a mounting aperture defined in an associated cabinet panel for fixedly securing said body to the associated cabinet panel;
located on a bottom edge of said body;
located on said rear side of said body.
